(19) United States
(12) Patent Application Publication
(10) Pub. No.: US 2004/0062123 A1
(43) Pub. Date: Apr. 1, 2004

(54) Nonvolatile semiconductor memory device able to detect test mode

(75) Inventor: Naotaka Yumoto, Minato-ku (JP)

Correspondence Address: NIXON PEABODY, LLP, 401 9TH STREET, NW, SUITE 900, WASINGTON, DC, 20004-2128, US

(73) Assignee: OKI ELECTRIC INDUSTRY CO., LTD., Tokyo (JP)

(21) Appl. No.: 10/670,219

(22) Filed: Sep. 26, 2003

Related U.S. Application Data
(60) Provisional application No. 60/413,947, filed on Sep. 27, 2002.

(51) Int. Cl. G11C 7/00

(52) U.S. Cl. 365/222

(57) ABSTRACT

A nonvolatile semiconductor memory device has a memory cell array having a memory cell and arranged in an array shape by connecting this memory cell to a bit line and a word line, an address input terminal inputting an address thereto, and a test mode circuit for outputting a test mode signal when a signal is inputted to a predetermined terminal among this address input terminal. The nonvolatile semiconductor memory device further has a row decoder connected to the test mode circuit and applying a voltage for a test to all the word lines in response to the test mode signal, a column decoder connected to the test mode circuit and setting all the bit lines to a non-selecting state in response to the test mode signal, and a monitor terminal connected to the test mode circuit and outputting the test mode signal.

### BACKGROUND OF THE INVENTION

This invention relates to a nonvolatile semiconductor memory device, and particularly relates to a nonvolatile semiconductor memory such as an ultraviolet erasing type PROM sealed in a plastic package not transmitting an ultraviolet ray.

A conventional nonvolatile semiconductor memory device has a test mode circuit. This test mode circuit applies a test mode voltage (e.g., the test mode voltage is set to 8 V when the normal high level is set to 5 V) higher than the normal high level to all word lines connected to the control gate of a memory cell in response to a signal from the exterior. On the other hand, the operations of column switches connected to one electrodes of the memory cells are controlled such that all the column switches are in a turning-off state.

Thus, electric field stress is applied to all the memory cells. The memory cell having an oxide film broken by this electric field stress is judged as a defective memory cell and a countermeasure such as the replacement of the defective memory cell with a redundant memory cell, etc. is taken.

However, in the conventional nonvolatile semiconductor memory device, the voltage is applied to only the interior of the device in this test mode, and this test mode has no means for confirming that the test mode is started from the exterior of a chip. Accordingly, a problem exists in that it is impossible to confirm that the electric field stress is applied to the device in a test process.

### SUMMARY OF THE INVENTION

This invention provides a nonvolatile semiconductor memory device able to confirm the test mode from the exterior.

A nonvolatile semiconductor memory device of this invention has a memory cell array having a memory cell and arranged in an array shape by connecting this memory cell to a bit line and a word line, an address input terminal inputting an address thereto, and a test mode circuit for outputting a test mode signal when a signal is inputted to a predetermined terminal among this address input terminal. The nonvolatile semiconductor memory device further has a row decoder connected to the test mode circuit and applying a voltage for a test to all the word lines in response to the test mode signal, a column decoder connected to the test mode circuit and setting all the bit lines to a non-selecting state in response to the test mode signal, and a monitor terminal connected to the test mode circuit and outputting the test mode signal.

### BRIEF DESCRIPTION OF THE DRAWINGS

FIG. 1 is a circuit diagram of a nonvolatile semiconductor memory device of a first embodiment of this invention.

FIG. 2 is a circuit diagram of a nonvolatile semiconductor memory device of a second embodiment of this invention.

FIG. 3 is a circuit diagram of a nonvolatile semiconductor memory device of a third embodiment of this invention.

FIG. 4 is a circuit diagram of a nonvolatile semiconductor memory device of a fourth embodiment of this invention.

### DETAILED DESCRIPTION OF THE PREFERRED EMBODIMENTS

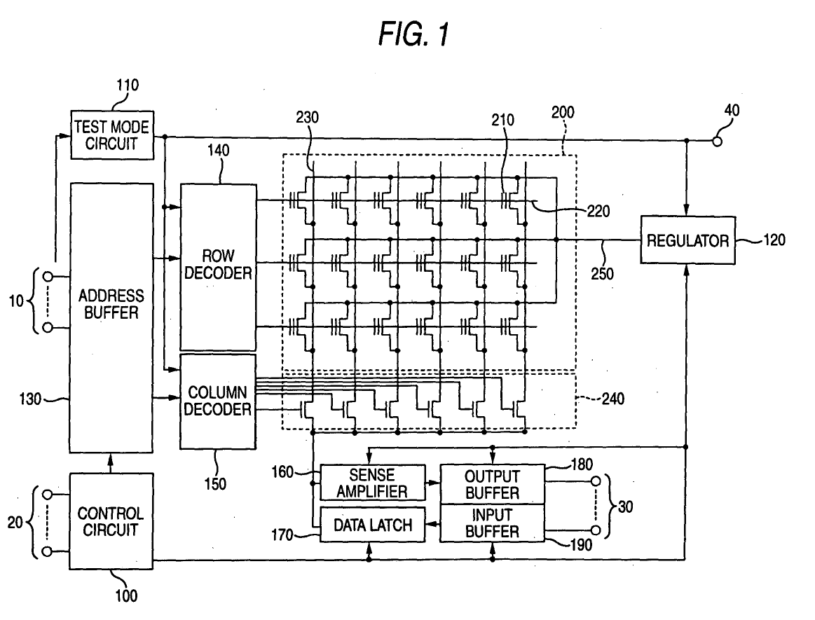

The nonvolatile semiconductor memory device of a first embodiment of this invention is constructed by a circuit as shown in FIG. 1. In FIG. 1, an address input terminal 10, a control signal input terminal 20 and a data input-output terminal 30 respectively receive an address signal, a control signal and data inputted from the exterior. The data input-output terminal 30 also has a function for outputting data to the exterior. A control circuit 100 receives a signal inputted from the control signal input terminal 20, and determines writing, reading, standby modes, etc., and controls the operations of other circuits. A test mode circuit 110 outputs a signal of a high voltage level when a voltage of 8 V is applied to the input of the test mode circuit 110. The signal outputted from the test mode circuit 110 is given to a regulator 120, and is also given to a monitor pad 40. A memory array 200 is constructed by plural memory cell transistors 210 having floating gates. The control gate of each memory cell 210 is connected to a word line 220. The drain of each memory cell 210 is connected to the regulator 120, and its source is connected to a bit line 230. The bit line 230 is connected to a column switch 240.

An address buffer 130 for receiving the address signal from the address input terminal 10 outputs the address signal to a row decoder 140 and a column decoder 150. The row decoder 140 and the column decoder 150 select the word line 220 and the column switch 240 in response to the address signal. The column switch 240 connects the selected bit line 230 to a sense amplifier 160 and a data latch circuit 170. Data read from the memory cell 210 are amplified by the sense amplifier 160, and are outputted from the data input-output terminal 30 through an output buffer 180. Further, data inputted from the data input-output terminal 30 are temporarily stored to the data latch circuit 170 through an input buffer 190.

Next, the writing operation of the nonvolatile semiconductor memory device of the first embodiment of this invention will be explained. The control circuit 100 outputs a signal by a control signal inputted from the control signal input terminal 20. The nonvolatile semiconductor memory device is set to a program inhibit mode by this outputted signal. At this time, the sense amplifier 160 and the output buffer 180 are inactivated. In this program inhibit mode, the address inputted from the address input terminal 10 is inputted to the row decoder 140 and the column decoder 150 through the address buffer 130. In contrast to this, the data inputted from the data input-output terminal 30 are held in the data latch circuit 170 through the input buffer 190. When it is changed to a program mode by the control signal from this state, the control gate of a memory cell 210 is selected through the word line 220 by a decode signal outputted from the row decoder 140. At this time, 8 V is applied to the selected word line 220. Simultaneously, 0 V is applied to an unselected word line. The drains of all the memory cells 210 are biased to 4.5 V by the regulator 120 through a select line 250. Further, the source of the memory cell 210 selected through the column switch 240 selected by a decode signal outputted from the column decoder 150 is connected to the data latch circuit 170 through the bit line 230. A voltage is applied to the bit line 230 from the data latch circuit 170 correspondingly to written data. In the case of data “1”, 3.0 V is applied to the bit line 230 and no electron is injected to the floating gate so that no threshold value of the memory cell 210 is changed. In the case of data “0”, 0 V is applied to the bit line 230 and the electron is injected to the floating gate so that the threshold value of the memory cell 210 is raised.

Next, the reading operation of the nonvolatile semiconductor memory device of the first embodiment of this invention will be explained. The nonvolatile semiconductor memory device is set to a reading mode by a control signal inputted from the exterior through the control signal input terminal 20. At this time, the input buffer 190 and the data latch circuit 170 are inactivated. In the reading mode, address information inputted from the address input terminal 10 is inputted to the row decoder 140 and the column decoder 150 through the address buffer 130. The control gate of a memory cell 210 is selected through the word line 220 by a decode signal of the row decoder 140. At this time, 3.3 V in standard is applied to the selected word line 220, and 0 V is applied to an unselected word line. Further, 1.5 V is applied to the drain of the memory cell 210 from the regulator through the select line 250. In contrast to this, one column switch 240 is selected by a decode signal of the column decoder 150. At this time, the source of the selected memory cell 210 is connected to the sense amplifier 160 through the bit line 230 and the column switch 240. Further, the selected bit line 230 is set to 0.1 V by the sense amplifier 160. The sense amplifier 160 converts the electric current of the memory cell 210 flowed from the selected bit line 230 into a voltage and outputs the converted voltage. This output of the sense amplifier 160 is transmitted from the data input-output terminal 30 to the exterior through the output buffer 180.

The memory cell 210 will next be explained. The floating gate of the normal memory cell 210 is insulated from its circumference by an oxide film. However, when the oxide film is broken and the floating gate becomes defective in the insulation after a product is forwarded, there is a case in which stored data are broken by the injection and emission of an unintentional electron and the memory cell becomes defective. To prevent this, it is necessary to remove the nonvolatile semiconductor memory device having the defective oxide film of the memory cell 210 in a test process. Therefore, 8 V is applied to all the word lines 220 by the test mode. Thus, the defective oxide film is removed by collectively applying an excessive voltage to the control gates of all the memory cells 210. This test mode will be further explained in detail.

When 8 V is applied to a specific terminal (e.g., the terminal of A8) among the address input terminal 10, the output signal of the test mode circuit 110 is selected. Thus, the nonvolatile semiconductor memory device is set to the test mode. The row decoder 140 selects all the word lines 220 and 8 V is applied to all the word lines 220 by applying 8 V to the specific terminal. Further, the bias voltage with respect to the select line 250 is removed by the regulator 120 and all the column switches 240 are simultaneously turned off to set all the bit lines 230 to a non-selecting state by the column decoder 150. Accordingly, electric field stress is applied to all the memory cells 210. At this time, since the output of the test mode circuit 110 is connected to the monitor pad 40, the output signal of the test mode circuit 110 is outputted to the monitor pad 40.

As explained above, in accordance with the first embodiment, the monitor pad 40 is arranged and the output of the test mode circuit 110 is connected to the monitor pad 40. Therefore, it is possible to confirm that the output of the test mode circuit 110 is selected by measuring the voltage of the monitor pad 40. Accordingly, it is possible to confirm that the nonvolatile semiconductor memory device starts the test mode. Thus, reliability of the test is improved and the nonvolatile semiconductor memory device can be forwarded by reliably removing the defective oxide film of the memory cell. In this case, the arrangement of the monitor pad in the first embodiment is a minus factor in reducing the size of a chip of the nonvolatile semiconductor memory device.

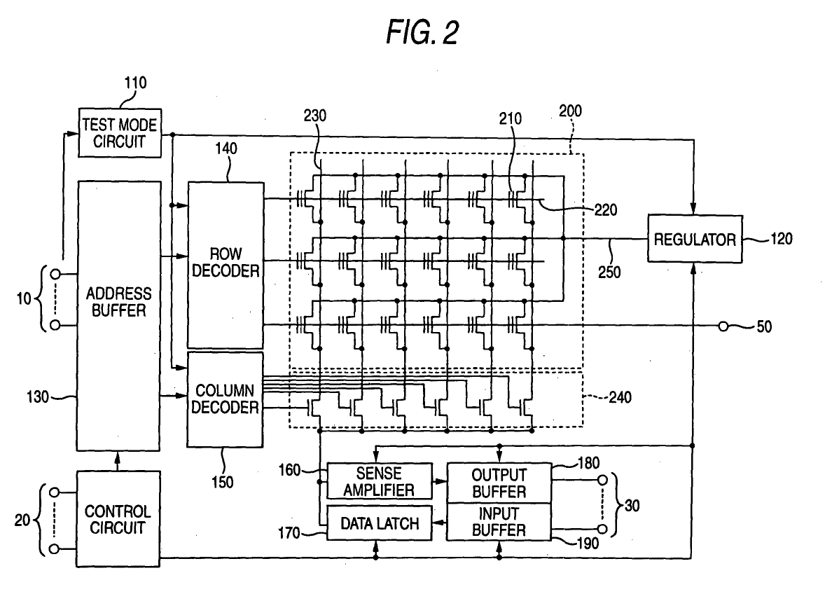

A second embodiment of this invention will next be explained. FIG. 2 is a circuit diagram of a nonvolatile semiconductor memory device of the second embodiment of this invention. In FIG. 2, the same portions as FIG. 1 are designated by the same reference numerals, and their explanations are omitted.

As can be seen from FIG. 2, in the nonvolatile semiconductor memory device of the second embodiment, a monitor pad 50 is connected to one of word lines 220 instead of the test mode circuit 110. The other constructions are the same as the first embodiment, and their explanations are therefore omitted.

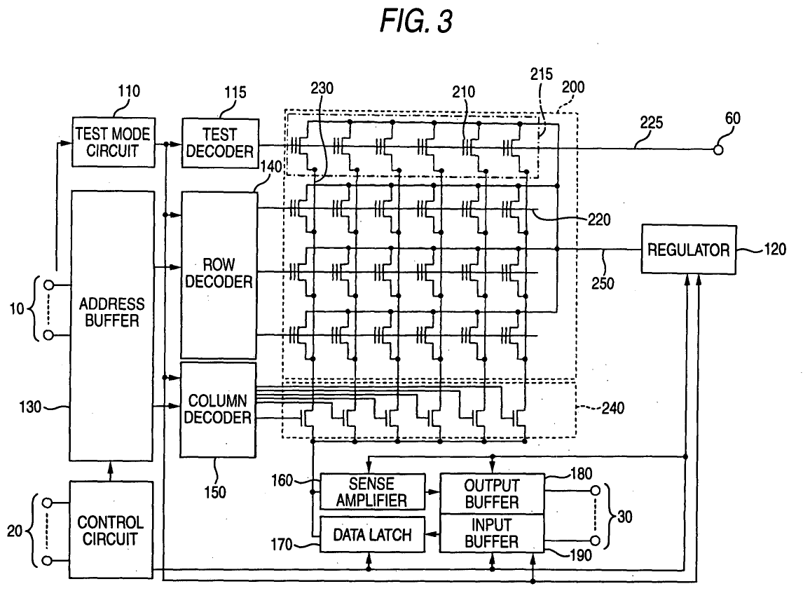

Next, the operation of the nonvolatile semiconductor memory device of the second embodiment will be explained with reference to FIG. 3. The reading and writing operations are the same as the first embodiment, and their explanations are therefore omitted. Accordingly, only the operation of a test mode will next be explained. The test mode circuit 110 outputs an output signal and the nonvolatile semiconductor memory device is set to the test mode by applying 8 V to a specific terminal of the address input terminal 10. 8 V is applied to all the word lines 220 since the row decoder 140 selects all the word lines 220 by the output signal of the test mode circuit 110. Further, the bias voltage with respect to the select line 250 is removed by the regulator 120. The column decoder turns off all the column switches 240 to set all the bit lines 230 to a non-selecting state. Thus, electric field stress is applied to all the memory cells 210. Since one word line among the word lines 220 is connected to the monitor pad 50, the voltage of the word line 220 is given to the monitor pad 50.

As mentioned above, since the monitor pad 50 is arranged and is connected to one of the word lines 220 in the second embodiment, the voltage of the word line 220 can be monitored at the test mode time. Accordingly, the application of the electric field stress can be reliably confirmed in comparison with the first embodiment. However, similar to the first embodiment 1, the arrangement of the monitor pad is a minus factor in reducing the chip size. Parasitic capacity of the monitor pad is added to the word line connected to the monitor pad. The parasitic capacity of the monitor pad is large to such an extent that no parasitic capacity can be neglected. Accordingly, there are demerits in that the rising of the word line is delayed and the delay of an access time is increased.

A third embodiment of this invention will be further explained. FIG. 3 is a circuit diagram of a nonvolatile semiconductor memory device of the third embodiment of this invention. In FIG. 3, the same portions as FIG. 2 are designated by the same reference numerals, and their explanations are omitted.

As can be seen from FIG. 3, a test decoder 115, a test cell 215, a test word line 225 and a monitor pad 60 are arranged in the nonvolatile semiconductor memory device of the third embodiment. The test decoder 115 is connected to the test mode circuit 110, and selects a test word line 225 in response to an output signal from the test mode circuit 110. Here, the test decoder 115 uses the same circuit as the row decoder 140, and the operation of the test decoder 115 is controlled by only the output signal of the test mode circuit 110. Similar to the normal word line 220, a memory cell transistor 210 is connected to the test word line 225. A memory cell connected to the test word line 225 is called a test cell 215. The test cell 215 is the same as the normal memory cell 210. Similar to the normal memory cell 210, the source of the test cell 215 is connected to a bit line 230, and its drain is connected to a select line 250. The test word line 225 is connected to the monitor pad 60. The other constructions are the same as the first embodiment, and their explanations are therefore omitted.

The operation of the nonvolatile semiconductor memory device of the third embodiment will next be explained with reference to FIG. 3. The reading and writing operations are the same as the first embodiment, and their explanations are therefore omitted. Only the operation of a test mode will next be explained. When 8 V is applied to a specific terminal of the address input terminal 10, the test mode circuit 110 outputs an output signal. Thus, the nonvolatile semiconductor memory device is set to the test mode. In the test mode, since the row decoder 140 selects all the word lines 220, 8 V is applied to all the word lines 220. Further, the bias voltage with respect to the select line 250 is removed by the regulator 120. Since the column decoder 150 sets all the bit lines to non-selection, the column decoder 150 sets all the column switches 240 to a turning-off state. Thus, electric field stress is applied to all the memory cells 210. Further, the test decoder 115 is activated by the output signal of the test mode circuit 110, and 8 V is also applied to the test word line 225. Accordingly, the electric field stress is also applied to the test cell 215, and the voltage applied to the test word line 225 is given to the monitor pad 60.

As mentioned above, in the third embodiment, the test decoder, the test cell and the test word line are arranged by using the same row decoder, memory cell and word line as the normal memory cell. Further, the test cell is arranged within a cell array of the normal memory cell, and the output of the test decoder is connected to the monitor pad through the test word line. Accordingly, the voltage of the word line can be monitored in the same condition as the normal memory cell. Thus, since the output of the test decoder is outputted to the monitor pad through the test word line arranged within the array, no word line capacity of the normal memory cell is increased as in the second embodiment. Therefore, no access delay is generated. Accordingly, the electric field stress can be reliably applied in the test process without damaging the performance of a chip. In this case, the arrangement of the monitor pad is a minus factor in reducing the chip area.

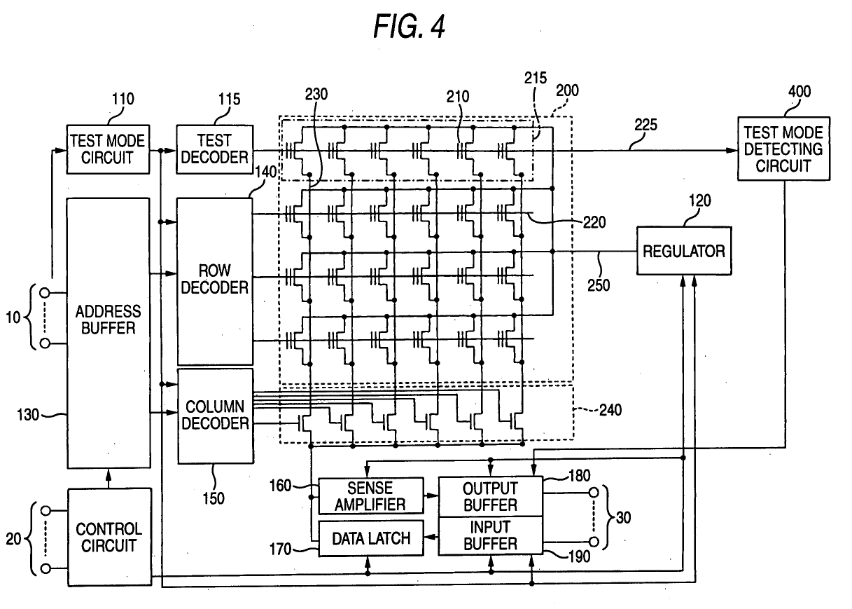

A fourth embodiment of this invention will next be explained. FIG. 4 is a circuit diagram of a nonvolatile semiconductor memory device of the fourth embodiment of this invention. In FIG. 4, the same portions as FIG. 3 are designated by the same reference numerals and their explanations are omitted.

As can be seen from FIG. 4, a test mode detecting circuit 400 is arranged instead of the monitor pad 60 in the nonvolatile semiconductor memory device of the fourth embodiment. The test mode detecting circuit 400 is connected to the test word line 225. The test mode detecting circuit 400 detects the electric potential of the test word line 225, and outputs its detecting result from the data input-output terminal through the output buffer 180. The other constructions are the same as the third embodiment, and their explanations are therefore omitted.

The operation of the nonvolatile semiconductor memory device of the fourth embodiment will next be explained with reference to FIG. 4. The reading and writing operations are the same as the first embodiment, and their explanations are therefore omitted. Accordingly, only the operation of a test mode will next be explained. The test mode detecting circuit 400 is arranged instead of the monitor pad 60 of the third embodiment in the nonvolatile semiconductor memory device of the fourth embodiment. When 8 V is applied to a specific terminal of the address input terminal 10, the test mode circuit 110 outputs an output signal. Thus, the nonvolatile semiconductor memory device is set to the test mode. In the test mode, since the row decoder 140 selects all the word lines 220, 8 V is applied to all the word lines 220. Further, the bias voltage with respect to the select line 250 is removed by the regulator 120. Since the column decoder 150 sets all the bit lines to non-selection, the column decoder 150 sets all the column switches 240 to a turning-off state. Thus, electric field stress is applied to all the memory cells 210. Further, the test decoder 115 is activated by the output signal of the test mode circuit 110, and 8 V is also applied to the test word line 225. Accordingly, the electric field stress is also applied to the test cell 215, and the voltage applied to the test word line 225 is detected by the test mode detecting circuit 400. The test mode detecting circuit 400 outputs the detecting result from the data input-output terminal 30 through the output buffer 180.

As explained above, in the nonvolatile semiconductor memory device of the fourth embodiment, the test decoder, the test cell and the test word line are arranged by using the same row decoder, memory cell and word line as the normal memory cell. Further, the test cell is arranged within a cell array of the normal memory cell, and the output of the test decoder is connected to the test mode detecting circuit. The output of this test mode detecting circuit is controlled by the output buffer and can be outputted to the chip exterior from the existing data input-output terminal. Accordingly, no monitor pad is required and the application of the electric field stress can be confirmed in the test process while an increase in chip area is restrained. Thus, reliability of the test is improved and the quality improvement of a product can be expected.

What is claimed is:

1. A nonvolatile semiconductor memory device comprising:
a memory cell array having plural memory cells and arranged in an array shape by connecting these memory cells to plural bit lines and word lines;
plural address input terminals inputting addresses thereto;
a test mode circuit for outputting a test mode signal when a signal is inputted to a predetermined terminal among these address input terminals;
a row decoder connected to said test mode circuit and applying a voltage for a test to all said word lines in response to said test mode signal;
a column decoder connected to said test mode circuit and setting all said bit lines to a non-selecting state in response to said test mode signal; and
a monitor terminal connected to said test mode circuit and outputting said test mode signal.

2. The nonvolatile semiconductor memory device according to claim 1, further comprising a select line connected to the drain of a memory cell, and a regulator connected to this select line and said test mode circuit and giving a predetermined bias electric potential to the drain of said memory cell.

3. The nonvolatile semiconductor memory device according to claim 1, further comprising a column switch connected to said column decoder and said bit line.

4. The nonvolatile semiconductor memory device according to claim 1, wherein said monitor terminal is a monitor pad.

5. The nonvolatile semiconductor memory device according to claim 1, further comprising a control signal input terminal for receiving a control signal, and a control circuit connected to this control signal input terminal.

6. A nonvolatile semiconductor memory device comprising:
a memory cell array having plural memory cells and arranged in an array shape by connecting these memory cells to plural bit lines and word lines;
plural address input terminals inputting addresses thereto;
a test mode circuit for outputting a test mode signal when a signal is inputted to a predetermined terminal among these address input terminals;
a row decoder connected to said test mode circuit and applying a voltage for a test to all said word lines in response to said test mode signal;
a column decoder connected to said test mode circuit and setting all said bit lines to a non-selecting state in response to said test mode signal; and
a monitor terminal connected to said word line and outputting the test mode signal given to said word line.

7. The nonvolatile semiconductor memory device according to claim 6, further comprising a select line connected to the drain of a memory cell, and a regulator connected to this select line and said test mode circuit and giving a predetermined bias electric potential to the drain of said memory cell.

8. The nonvolatile semiconductor memory device according to claim 6, further comprising a column switch connected to said column decoder and said bit line.

9. The nonvolatile semiconductor memory device according to claim 6, wherein said monitor terminal is a monitor pad.

10. The nonvolatile semiconductor memory device according to claim 6, further comprising a control signal input terminal for receiving a control signal, and a control circuit connected to this control signal input terminal.

11. A nonvolatile semiconductor memory device comprising:
a memory cell array having plural memory cells and arranged in an array shape by connecting these memory cells to plural bit lines and word lines;
a test cell having plural memory cells which are connected to said word lines and are also connected to a test word line;
plural address input terminals inputting addresses thereto;
a test mode circuit for outputting a test mode signal when a signal is inputted to a predetermined terminal among these address input terminals;
a row decoder connected to said test mode circuit and applying a voltage for a test to all said word lines in response to said test mode signal;
a column decoder connected to said test mode circuit and setting all said bit lines to a non-selecting state in response to said test mode signal;
a test decoder connected to said test mode circuit and applying the voltage for a test to said test word line in response to said test mode signal; and
a monitor terminal connected to said test word line and outputting the voltage for a test applied to said test word line.

12. The nonvolatile semiconductor memory device according to claim 11, further comprising a select line connected to the drain of a memory cell, and a regulator connected to this select line and said test mode circuit and giving a predetermined bias electric potential to the drain of said memory cell.

13. The nonvolatile semiconductor memory device according to claim 11, further comprising a column switch connected to said column decoder and said bit line.

14. The nonvolatile semiconductor memory device according to claim 11, wherein said monitor terminal is a monitor pad.

15. The nonvolatile semiconductor memory device according to claim 11, further comprising a control signal input terminal for receiving a control signal, and a control circuit connected to this control signal input terminal.

16. A nonvolatile semiconductor memory device comprising:
a memory cell array having plural memory cells and arranged in an array shape by connecting these memory cells to plural bit lines and word lines;
a test cell having plural memory cells which are connected to said word lines and are also connected to a test word line;
plural address input terminals inputting addresses thereto;
a test mode circuit for outputting a test mode signal when a signal is inputted to a predetermined terminal among these address input terminals;
a row decoder connected to said test mode circuit and applying a voltage for a test to all said word lines in response to said test mode signal;
a column decoder connected to said test mode circuit and setting all said bit lines to a non-selecting state in response to said test mode signal;
a test decoder connected to said test mode circuit and applying the voltage for a test to said test word line in response to said test mode signal; and
a test mode detecting circuit connected to said test word line and detecting the voltage for a test applied to said test word line and outputting the detecting result.

17. The nonvolatile semiconductor memory device according to claim 16, further comprising a select line connected to the drain of a memory cell, and a regulator connected to this select line and said test mode circuit and giving a predetermined bias electric potential to the drain of said memory cell.

18. The nonvolatile semiconductor memory device according to claim 16, further comprising a column switch connected to said column decoder and said bit line.

19. The nonvolatile semiconductor memory device according to claim 16, further comprising a control signal input terminal for receiving a control signal, and a control circuit connected to this control signal input terminal.

20. The nonvolatile semiconductor memory device according to claim 16, wherein the nonvolatile semiconductor memory device further comprises a data input-output terminal, and the detecting result of said test mode detecting circuit is outputted from said data input-output terminal.
